(19) United States
(12) Patent Application Publication
(10) Pub. No.: US 2026/0050208 A1
(43) Pub. Date: Feb. 19, 2026

(54) REMOTE-PLASMA ELECTRON-INDUCED MASK REPAIR

(71) Applicant: Carl Zeiss SMT GmbH, Oberkochen (DE)

(72) Inventors: Christian Preischl, Mainz (DE); Daniel Rhinow, Frankfurt (DE); Hubertus Marbach, Grossostheim (DE); Michael Budach, Hanau (DE); Klaus Edinger, Lorsch (DE)

(21) Appl. No.: 19/368,017

(22) Filed: Oct. 24, 2025

Related U.S. Application Data
(63) Continuation of application No. PCT/EP2024/059125, filed on Apr. 4, 2024.
(60) Provisional application No. 63/462,283, filed on Apr. 27, 2023.

(51) Int. Cl. G03F 1/74

(52) U.S. Cl. CPC G03F 1/74

(57) ABSTRACT

The present invention relates to an apparatus for processing an object (O) comprising: an activator (A) for activating a precursor gas (P) to generate a component (C) from the precursor gas; a guide (G) for providing the component locally on the object; a beam unit (BU) for providing a particle (B) beam on the object. Further aspects relate to an according method and computer program.

### CROSS-REFERENCE TO RELATED APPLICATIONS

This application is a continuation of and claims benefit under 35 U.S.C. § 120 from PCT application PCT/EP2024/059125, filed on Apr. 4, 2024, which claims the priority of U.S. provisional patent application 63/462,283, entitled “Remote-Plasma Electron-Induced Mask Repair,” filed on Apr. 27, 2023. The entire contents of each of these earlier applications are incorporated herein by reference.

### TECHNICAL FIELD

The present invention relates to a processing of objects. In particular, the invention relates to a processing of an object with a particle beam and a component generated from a precursor gas. To that regard, the invention comprises an according apparatus, method and computer program.

### BACKGROUND

In the field of semiconductor technology various methods and devices for processing an object are known. For example, the processing may comprise removing a material of the object in a defined manner.

The removing of the material may be implemented by exposing the object to a chemical (e.g., a precursor gas) and additionally exposing the object to particles (e.g., electrons, photons, ions or a combination thereof). In such an example, the particles may induce a reaction in combination with the chemical such that a material of the object is removed. Such a particle induced chemical reaction may highly depend on the characteristics of the used chemical (e.g., the precursor gas). It may thus be desired from a technical standpoint to use a specific chemical (e.g., a specific precursor gas) to ensure a controlled removal of the material.

However, a specific chemical which may be advantageous for a specific particle induced reaction may not always have optimal characteristics with respect to a technical boundary condition (e.g., regarding an industrial application and/or a control of the particle induced reaction).

Hence, the currently known techniques for processing objects are not always optimal. Therefore, there is a need to find ways to improve the processing of objects.

### SUMMARY

The aspects described herein address the above need at least in part.

A first aspect relates to an apparatus for processing an object. The apparatus may comprise an activator for activating a precursor gas to generate a component from the precursor gas; a guide for providing the component locally on the object. The apparatus may further comprise a beam unit for providing a particle beam on the object.

For example, the activator may be configured to activate the precursor gas by a chemical and/or physical activation. This may comprise inducing a chemical and/or physical reaction of the precursor gas, for example. This may be achieved by applying an energy to the precursor gas via the activator. The component generated from the precursor gas may comprise a product of the induced chemical and/or physical reaction of the precursor gas. The precursor gas can, for example, be regarded as a raw material (e.g., a reactant), wherein the component is a substance that can be generated out of the raw material (i.e., the precursor gas) via the activator within the apparatus.

To illustrate an example, the precursor gas may initially be in a first (chemical and/or physical) state. In the first state, the precursor gas may comprise one or more chemical elements of the periodic table. The one or more chemical elements may serve as building blocks to generate a component therefrom. For example, in the first state, the one or more chemical elements may be arranged in the form of atoms, molecules, ions and/or any other type of chemical bond. By activating the precursor gas, e.g., by providing energy to the precursor gas, at least a portion of the precursor gas may be transformed into a second (chemical and/or physical) state. In the second state, the one or more chemical elements may be (at least in part) arranged in a different manner compared to the first state. The different arrangement of the chemical elements may comprise a component generated from the precursor gas.

To illustrate an example of the generated component, in the first state the precursor gas may not comprise atoms and/or molecules with an unpaired valence electron. In the second state, atoms and/or molecules with an unpaired valence electron may be present. In such an example, the atoms and/or molecules with an unpaired valence electron (e.g., (free) radicals) may be regarded as the generated component. Notably, it may also be the case that the concentration of atoms and/or molecules with an unpaired valence electron may be different in the second state compared to the first state. For example, the concentration of atoms and/or molecules with an unpaired valence electron may be increased in the second state compared to the first state. The activation may thus, for example, also be used to generate more of a component which was already present in the first state.

To illustrate a further example of the generated component, the electron state and/or electron configuration of an atom, molecule, ion and/or any other type of chemical compound may be different in the second state compared to the first state. For example, one or more electrons may be removed from (or added to) an atom, molecule, ion and/or any other type of chemical compound that was present in the first state.

To illustrate a further example of a generated component, an atom, a molecule, an ion and/or any other type of chemical compound may be present in the second state which was not present in the first state. In such an example, the new atom, new molecule, new ion and/or new type of chemical compound may be regarded as the generated component. Notably, it may also be the case that the concentration of an atom, a molecule, ion and/or any other type of chemical compound may be different in the second state compared to the first state. For example, the concentration of an atom, a molecule, ion and/or any other type of chemical compound may be increased (or decreased) in the second state compared to the first state. The activation may thus (as described herein) also be used to generate more (or less) of a component which was already present in the first state. For example, from O₂ molecules comprised by the precursor gas, O₃ molecules may at least in part be generated as a component.

Notably, one or more atoms, molecules and/or any other types of chemical bonds which were present in the first state may not be present in the second state (or to a lower extent) due to the generation of the component.

The apparatus may thus particularly enable to generate a component from the precursor gas via the activator, wherein the component was not (substantially) present in the precursor gas itself. For example, the generated component may not be present in the precursor gas at all or may only be present in a comparably low (e.g., insignificant) concentration such that a reaction with the object would not (significantly) occur. Hence, according to the invention the component does not need to be stored within the apparatus but may be generated in situ within the apparatus.

For example, the activator may thus enable to generate a component which may be advantageous for processing the object, but which may not have favorable storage characteristics (e.g., a component which may not be (easily) stored in a stable, secure and/or reliable manner). Due to the activator, it may suffice to store the precursor gas (or the gases making up the precursor gas) which may have more advantageous storage characteristics.

For example, some chemicals (which may be advantageous for the particle induced reaction) may not always comprise stable and/or desirable storage characteristics. In such a case a reliable storage of the chemical may not always be ensured or may require a sophisticated storage technology, complex safety precautions and/or high maintenance effort. Usually, the strong drawbacks of storing unstable chemicals may not be overcome in an industrial setting. Known approaches may thus be limited to the use of stable chemicals for particle induced reactions. This limitation may be overcome at least in part by the aspects described herein.

For example, a precursor gas with an advantageous storage characteristic may comprise a precursor gas which is chemically stable over a prolonged period of time (e.g., over months or years). A precursor gas with an advantageous storage characteristic may also comprise a precursor gas with a comparably high vapor pressure.

To that regard, the apparatus may enable to generate a component which would not be chemically stable over a prolonged period of time (e.g., a component which is not stable for at least 1 hour, 1 day, 1 month, 1 year), for example.

In another example, the apparatus may enable to generate a component from the precursor gas, wherein the component has a lower vapor pressure than the vapor pressure of the precursor gas.

To illustrate another example, a precursor gas with an undesired storage characteristic may comprise a precursor gas which may comprise explosive characteristics. For example, some gases may explode under the impact of shock, friction and/or vibration. According to the invention, the apparatus may enable to generate a component from the precursor gas, wherein the component may comprise the stated undesired explosive characteristics but the stored precursor gas itself would (substantially) not comprise such explosive characteristics.

Overall, the apparatus may enable to store a stable precursor gas wherein a highly reactive and/or unstable component may be generated from the precursor gas which may be beneficial for processing the object.

In addition, the apparatus may enable to provide the component locally on the object via the guide of the apparatus.

For example, the guide may comprise a conduit such that the component may move from the activator (at least partly) through the conduit. In an example, the activator may be configured to eject the component such that the component is transported into an input opening of the guide. The guide may further comprise an output opening wherein the component may be released from the output opening such that the component can be provided locally on the object.

For example, a highly reactive chemical (which may be advantageous for the processing of the object) may not be easily controllable. Known approaches may thus rely on simply providing the chemical globally over the entire object to minimize process control (e.g., by simply flooding the entire chamber that comprises the object with the chemical). However, the process control in such an example, may be limited to a global control of the chemical. This may limit potential control of processing the object and/or may require further maintenance effort (e.g., due to the chemical affecting the entire object and/or the entire chamber comprising the object).

However, the apparatus according to the invention may not (necessarily) be configured to provide the generated component in a global manner over the entire object. Rather, by use of the guide the component can be ejected locally onto a part of the object. Thus, a local part of the object may comprise a higher concentration of the component than another local part of the object. For example, providing the component locally on the object may induce a concentration gradient of the component over the object or (at least) over a part of the object. The 20) concentration gradient may comprise a concentration gradient which may not be engineered when the component is provided in a global manner over the entire object (e.g., when exposing the entire surface of the object to the component).

Hence, the apparatus may enable a higher degree of freedom for processing the object since certain parts of the object may be exposed to the component with a higher concentration than other parts in a defined manner.

Notably, the apparatus may further comprise a beam unit for providing a particle beam on the object. The particle beam may comprise charged and/or uncharged particles as well as massive and/or massless particles. For example, the particle beam may comprise an electron beam, an ion beam, a photon beam and/or combinations thereof. For example, the beam unit may provide at least one electron beam which may impinge on the object. It may also be conceivable, that the beam unit may provide an electron beam and at least one type of ion beam. In another example, the beam unit may provide at least two types of ion beams (wherein an electron beam may not necessarily be provided on the object). In an example, the beam unit may be configured for providing the particle beam locally on the object. For example, the beam unit may comprise a beam focusing element for focusing the particle beam onto the object. However, the particle beam may also be provided locally on the object without (necessarily) focusing the particle beam. The beam unit may also comprise a beam deflection element for deflecting and/or providing the particle beam onto a desired position of the object. The beam unit may be configured to provide the particle beam within a part of the object that is exposed to the component.

For example, the apparatus may thus enable to induce a particle induced reaction of the component with a material of the object by providing the component locally on the object and also providing particles on the object (e.g., within the same part of the object, e.g., a reaction area of the object). The particle induced reaction may, for example, induce a removal of material of the object (although other types of reactions may also be conceivable with the apparatus).

To that regard, the guide and the activator may enable a more effective particle induced reaction with the material of the object compared to known approaches that rather rely on providing a chemical globally over the entire object.

Namely, to ensure an effective particle induced reaction a sufficient concentration (or sufficient pressure) of the component should be present at a reaction area of the particle induced reaction. By providing the component locally on the object (by use of the guide) according to the invention a high concentration of the component can be easily generated at the reaction area. Namely, the inventive approach may require a comparatively small total amount of the component to reach a sufficient concentration at the reaction area since it is not the entire surface of the object that needs to be exposed to the component.

Known approaches may in contrast rather rely on flooding the entire object with a chemical to ensure a high amount of concentration thereof at every part of the object (e.g., to ensure a high global pressure of the chemical). However, this may require a comparatively high amount of chemical compared to the inventive concept while also exposing and affecting the entire object with the chemical (which may not always be desired for processing the object).

The apparatus according to the invention, may in turn enable that not only a high local concentration of the component can be easily generated at the reaction area but also that the component itself may comprise a highly reactive component which may be unstable to store.

Namely, this functionality is enabled by the guide and the activator. To emphasize, the guide may enable to provide a high concentration needed for the particle induced reaction. The activator may enable to provide a highly reactive component for the reaction (based on an easily storable precursor gas). These two structures combined may thus, for example, enable an apparatus that can be used to implement a more effective particle induced reaction with a material of the object.

The apparatus may comprise an object holder for holding the object. The object may comprise an object of the semiconductor industry. The apparatus may comprise one or more object holders for securely holding the object. For example, the object holder may comprise a holder for an object for lithography. The object for lithography may comprise a mask that is used for a specific type of lithography (e.g., UV-lithography, DUV-lithography, EUV-lithography, High-NA-EUV-lithography, nanoimprint lithography, or any other type of lithography). The mask may, for example, comprise a binary mask or a phase shifting mask for a specific type of lithography. The object for lithography may also comprise a mask blank which may comprise the base material for a mask (as known in the semiconductor industry). For example, the object holder may comprise a mask chuck.

The object of the semiconductor industry may also comprise a semiconductor-based wafer. For example, the wafer may comprise a semiconductor (e.g., silicon, gallium arsenide, silicon carbide, gallium nitride, etc.). In an example, the wafer may be processed (and may thus comprise structured features or even functioning chips). To that regard the wafer may also comprise one or more metals which may be part of the structured features. For example, the object holder may comprise a wafer chuck.

The object of the semiconductor industry may also comprise a microchip. The microchip may, for example, be in an unpackaged stage. The apparatus may be used to process a specific part of the microchip (e.g., a specific electrical part of the microchip). For example, the object holder may comprise a chuck for a microchip and/or object holders as used for scanning electron microscopy.

Notably, the object may comprise any other type of object where a particle induced reaction may be evoked.

Subsequently, the apparatus is described in more detail.

In an example, the guide may be configured such that the component can be provided on a subarea of the object such that substantially only the subarea is exposed to the component. The guide may thus be configured that not only a concentration gradient of the component may be generated over the object but also that certain parts of the object are not exposed to the component. In an example, the parts not exposed to the component (e.g., parts outside of the subarea) may be regarded as non-reactive parts of the object. Notably, also in such non-reactive parts a fraction of the component may be present. However, the concentration of the component in the non-reactive parts may not suffice for a particle induced reaction via the particle beam. To illustrate an example, if the particle beam were provided within the non-reactive parts, no particle induced reaction would occur. In contrast, if the particle beam were provided within the subarea, the particle beam would initiate a particle induced reaction with a material of the object. The subarea may thus be regarded as a processing area of the object.

The guide configuration (as described herein) and/or the adaptation of the flow of the component within the guide may enable a tuning of the dimensions of the subarea.

In an example, the subarea may comprise a subarea with a diameter of at most 10 mm. In another example, the subarea may comprise a subarea with a diameter of at most 5 mm. In another example, the subarea may comprise a subarea with a diameter of at most 3 mm. In another example, the subarea may comprise a subarea with a diameter of at most 1 mm.

In an example, the subarea may comprise a (substantially) circular or elliptical shape wherein the diameter of the subarea may accordingly comprise a diameter defined by the circular or elliptical shape. In an example, the subarea may comprise a (substantially) rectangular or square shape wherein the diameter of the subarea may accordingly comprise a diameter defined by the rectangular or square shape.

In an example, the subarea may be adapted with respect to the area of the object. For example, the subarea may comprise at most 1% of the area of the object. In other examples, the subarea may comprise at most 2%, at most 10%, at most 20%, at most 30%, at most 40%, at most 50%, or at most 60% of the area of the object.

In an example, the apparatus may have a first chamber comprising a holder for the object, wherein the guide extends at least in part within the first chamber. For example, the guide may extend within the first chamber such that the output opening of the guide would be positioned above the object if the object would be placed on the holder. The holder may comprise a chuck (e.g., an electrostatic chuck or any other type of chuck). The holder may further comprise a positioning stage for positioning the object onto a desired position within the first chamber.

In an example, the guide may also be positionable within the first chamber. For example, the guide may be positioned via an according guide movement unit. The guide movement unit may be configured to move the guide such that the output opening of the guide may be above a desired position of the object when the object is placed on the holder.

The subarea that is exposed to the component may thus be set by the apparatus via moving the object and/or via moving the guide itself.

In an example, in a processing position of the object an opening of the guide which releases the component onto the object may be spaced from the object by at most 10 cm, by at most 1 cm, by at most 100 μm, or by at most 10 μm. The opening which releases the component onto the object may also be referred to herein as the output opening of the guide. According to the invention, the output opening of the guide may be brought into the near vicinity of the object. This may ensure to reliably create a local high concentration of the component (e.g., a high local pressure of the component) needed for the particle induced reaction.

The processing position of the object may comprise a position of the holder with the object being placed thereon wherein a particle induced reaction may occur in the processing position. Hence, in the processing position the particle beam and the component may be provided locally on the object to effectively process a material of the object.

In an example, the spacing distance between the output opening of the guide and the object may be adjusted by the apparatus by moving the holder and/or the guide.

In an example, an inner wall of the guide may comprise a coating which is substantially resistant to the component. As described herein, the component may comprise a chemically highly reactive component. Hence, the component may induce significant wear, erosion and/or abrasion effects within the guide if no technological precautions are implemented. The coating of the inner wall of the guide may thus be tailored to one or more highly reactive components that may be generated from the precursor gas to minimize or eliminate a reaction of the component with the inner wall of the guide. The coating may thus minimize maintenance effort (e.g., cleaning of the guide) and/or replacing the guide due to the mentioned effects while ensuring that a highly reactive component can nonetheless be locally provided on the object to enable an effective particle induced reaction. Hence, via the respective coating a more reliable functionality of the apparatus may be attained within an industrial setting.

In an example, the coating may comprise at least one of the following materials or a combination thereof: Teflon, steel, a plastic, a dielectric material. The steel of the coating may, for example, comprise stainless steel and/or corrosion resistant steel. The plastic of the coating may, for example, comprise FKM (a family of fluorocarbon-based fluoroelastomer materials), PTFE (Polytetrafluoroethylene), PFA (Perfluoroalkoxy alkanes).

In an example, the coating may be configured (and/or comprise one or more materials) such that the component may not be deactivated and/or neutralized by the coating. For example, the coating may be configured such that the component may not be deactivated and/or neutralized when the component comes into contact with the coating.

In an example, different segments of the guide may comprise different coating materials. For example, a first segment of the guide may comprise a first coating material, a second segment of the guide may comprise a second coating material different than the first coating material.

In an example, the guide may comprise different segments wherein different segments may have different guide diameters (e.g., inner or outer conduit diameters). For example, the guide may comprise a first segment having a first diameter (e.g., a first inner or outer conduit diameter) and a second segment having a second diameter (e.g., a second inner or outer conduit diameter), wherein the second diameter may be different than the first diameter.

For example, a guide diameter of the guide may be in the range between 0.5 mm and 30 cm. For example, one or more segments of the guide may have guide diameters in the mm-range (e.g., with a guide diameter between 0.5 mm and 10 mm). For example, one or more segments of the guide may have guide diameters in the cm-range (e.g., with a guide diameter between 1 cm and 30 cm).

In an example, the guide may comprise a guide diameter of at least 0.5 mm, at least 5 mm, at least 1 cm, at least 5 cm, at least 10 cm, at least 15 cm, at least 20 cm and/or at least 25 cm.

In an example, the guide may comprise a guide diameter of at most 30 cm, at most 25 cm, at most 20 cm, at most 15 cm, at most 10 cm, at most 5 cm, at most 1 cm, at most 5 mm, or at most 0.6 mm.

In an example, the guide may comprise a length of at most 10 cm. In another example, the guide may comprise a length of at most 50 cm, at most 1 m, at most 2 m, at most 3 m, at most 4 m, or at most 5 m.

In an example, the guide may comprise a wall thickness (which may also comprise the coating) between 0.1 mm and 30 cm.

In an example, the guide may comprise different segments wherein different segments may have different wall thicknesses. For example, a first segment of the guide may comprise a first wall thickness, a second segment of the guide may comprise a second wall thickness different than the first wall thickness.

In an example, the activator may be separated from the object such that the object is not subjected to a reaction of the activating of the precursor gas. For example, the activator may be located separately from the object (or the object holder) such that the chemical and/or physical reaction of the precursor gas evoked by the activator may not impact the object itself. For example, the activator may be spaced from the object such that the entire activated precursor gas may not interact with the object. According to the invention, rather a set of one or more components present in the activated precursor gas can be extracted therefrom to the guide such that only the set of one or more components comes into (local) contact with the object.

Notably, it may not be desirable to suspend the entire object to the reaction of generating the component from the precursor gas. For example, the activated precursor gas may comprise other components which may not be beneficial for a particle induced reaction. Furthermore, a (local) particle induced reaction may not even be possible when suspending the object globally to the activation of the precursor gas (e.g., as this may induce an uncontrollable scattering of the particle beam such that a local reaction may not be induced via the particle beam).

In an example, the apparatus may have a second chamber comprising the activator, wherein the second and first chambers are coupled at least in part via the guide such that the component may be transported from the second chamber to the first chamber. In this example, the apparatus may thus comprise at least two chambers, namely the first chamber comprising the holder for the object (and thus, e.g., comprising the object) and the second chamber comprising the activator. The activation of the precursor gas may thus be implemented in a different chamber than the chamber where the actual processing of the object with the generated component occurs. The second chamber may thus function as an activation chamber for the chemical and/or physical activation of the precursor gas. The object itself which may reside in the first chamber will in this example, not be affected by the chemical and/or physical reaction that takes place for the activation of the precursor gas. The guide may function as a coupling element between the spatially separated first and second chambers to guide the component generated in the second chamber to the object residing in the first chamber.

In an example, the activator may comprise a plasma unit to form a plasma for activating the precursor gas. For example, the plasma unit may be configured to form a plasma of the precursor gas. To illustrate an example, the plasma unit may be configured to receive the precursor gas and to ignite a plasma of the precursor gas. The plasma of the precursor gas may correspond to the activated precursor gas (as described herein). Notably, the plasma of the precursor gas may (in particular) correspond to the second chemical state of the precursor gas (as described herein). The chemical elements of the precursor gas do not change when the precursor gas is transformed into a plasma. However, a variety of highly reactive components or new chemical compounds may be present in the plasma of the precursor gas which were not present in the (initial, not activated) precursor gas itself.

The plasma unit may comprise any plasma forming unit that may excite the precursor gas (e.g., via an energetic excitation) such that a plasma of the precursor gas is generated. For example, the plasma unit may comprise one or more electrodes to apply an electrical field that extends within the precursor gas to form a plasma of the precursor gas (as known in the field).

Notably, the plasma unit may be configured such that a precursor gas may be received which may comprise atoms and/or molecules that are beneficial to ignite a plasma. For example, the precursor gas may comprise (inter alia) Argon wherein the plasma unit may be configured to excite the argon atoms to generate a plasma of the precursor gas.

In an example, the component may comprise a component of the plasma. For example, the component generated from the precursor gas may comprise a radical, atom and/or molecule of the plasma.

In an example, the activator may comprise a radiation unit to irradiate the precursor gas with electromagnetic radiation to ionize the precursor gas for activating the precursor gas. Notably, the radiation unit may be configured to ionize one or more atoms or molecules of the precursor gas. In this example, a plasma of the precursor gas may not (necessarily) be formed by the radiation unit. The radiation unit may, for example, comprise an ultra-violet radiator wherein the electromagnetic radiation may comprise ultra-violet radiation generated from the ultra-violet radiator. The radiation unit may, for example, comprise a microwave radiator wherein the electromagnetic radiation may comprise microwave radiation generated from the microwave radiator. Notably, the radiation unit may comprise any type of radiator to generate an electromagnetic radiation that is capable to ionize one or more atoms or molecules of the precursor gas.

In an example, the component may comprise a component of the ionized precursor gas. For example, the component generated from the precursor gas may comprise a radical, atom and/or molecule of the ionized precursor gas.

In an example, the component may comprise a radical and/or a chemical compound not substantially present in the precursor gas. For example, the activator may generate (e.g., via the plasma unit and/or the radiation unit) an atom, ion and/or molecule which was not present in the precursor gas.

In an example, the apparatus may comprise a filter for filtering a specific component out of a plurality of components generated from the precursor gas such that the specific component is provided locally on the object.

In an example, a net charge of the component may be substantially neutral (or substantially zero).

In an example, a net charge of the component may be substantially positive or negative.

To that regard, the filter may be configured for filtering a specific component based on the net charge of the component.

In an example, the filter may comprise an ion filter and/or a neutralization plate. The ion filter may comprise any type of ion filter that may enable that only one or more specifically charged components may be extracted at the filter output. The apparatus may be configured such that the filter output and/or the neutralization plate output may be coupled to the guide such that the filtered component is provided locally on the object.

For example, the ion filter may comprise a field unit for generating an electrical and/or magnetic field. The field unit may be placed within the apparatus such that components of the activated precursor gas may be subjected to the electrical and/or magnetic field. Depending on an adjustment of the electrical and/or magnetic field only one or more specifically charged components may be guided to the filter output of the field unit. For example, the field unit may be configured to deflect components with a net charge other than zero from the filter output wherein components having a neutral net charge may move to the filter output unaffected by the electrical and/or magnetic field of the field unit. However, the field unit may also be configured such that charged components may be extracted at the filter output (and thus provided locally on the object).

The ion filter may also comprise a filter which may absorb a specific type of charged component such that the not absorbed components may be present at the filter output.

For example, the neutralization plate may comprise an electrically conductive plate which may be electrically grounded (e.g., set to a potential of zero Volts). The neutralization plate may thus enable that only neutral components can diffuse through it. The components having a net charge other than zero may be absorbed by the neutralization plate and thus filtered out. The neutralization plate may thus also be considered and/or function as an ion filter.

In an example, the apparatus may be configured to set the guide on a predetermined electric potential to filter the specific component. In this example, the guide itself may function as an ion filter (similar as described for the neutralization plate). For example, the guide may be electrically grounded (e.g., wherein the predetermined electric potential is set to zero Volts). In such an example, only the electrically neutral components may be guided through the guide unaffected. The components having a positive or negative charge, however, may be conducted towards the guide due to its electric potential and may thus be absorbed by the guide.

In a preferred example, the apparatus may be configured such that only electrical neutral components may be guided onto the object. In such an example, the herein described filter mechanics or combinations thereof may thus be configured to filter out charged components.

In an example, the activator may be configured to eject the component in a beam to the guide. For example, the activator may comprise an aperture and/or a nozzle such that components of the activated precursor gas may be ejected out of the activator through the aperture and/or the nozzle. The aperture may be in the form of a simple opening within the activator. The diameter of the aperture may be adjustable (e.g., for adjusting the flow of the ejected components). Notably, the nozzle may also be adjustable (e.g., for adjusting the flow and/or speed of the ejected components). It may also be conceivable that the activator may comprise an ejection unit wherein the ejection unit may comprise an ejection system which may comprise one or more apertures and/or nozzles.

As described herein, the apparatus may comprise a second chamber comprising the activator. The second chamber may, for example, comprise a vacuum chamber. In such an example, the activator may be configured to eject the component in a beam into a part of the second chamber such that the particles of the beam may travel through the vacuum of the second chamber into the guide. To illustrate an example, the activator may comprise a plasma unit (as described herein). In such an example, the plasma unit may comprise an aperture and/or a nozzle such that components of the plasma may be ejected out of the aperture and/or nozzle into the vacuum of the second chamber.

Notably, the components ejected in a beam from the activator may comprise a relatively broad angular distribution.

In an example, the apparatus may comprise a beam shaper to shape the beam of the component ejected from the activator. The beam shaper may, for example, comprise a collimating element to collimate the ejected beam. The beam shaper may, for example, comprise a skimmer in the shape of a funnel. The skimmer may, for example, comprise a shape as known for a molecular beam skimmer. The skimmer may enable to reduce the angular distribution of the beam ejected from the activator. Hence, the skimmer may enable to collimate the ejected beam.

In an example, the beam shaper may be positioned such that the shaped beam may substantially be collimated into the input opening of the guide. To that regard, the beam diameter may, for example, fully reside within the input opening of the guide.

In an example, the apparatus may comprise at least one reaction gas container for providing the precursor gas, wherein the at least one reaction gas container is configured to store at least one of the following: a reaction gas comprising a halide, a reaction gas comprising oxygen, a reaction gas comprising hydrogen. Notably, the precursor gas may comprise a reaction gas from a reaction gas container. To that regard, the apparatus may, for example, comprise a gas line system to provide a reaction gas from the at least one reaction gas container to the activator.

The reaction gas container may, for example, be adapted such that a reaction gas comprising a halide may be reliably stored. For example, the reaction gas container may comprise an inner coating such that a gas with halide may not (substantially) interact with the (inner) material of the reaction gas container. The gas comprising a halide may comprise at least one halogen atom. For example, the gas comprising a halide may comprise at least one of the following: XeF₂, CF₄, CCl₄, Cl₂, HCl, HF, I₂, HI, Br₂, HBr, NOCl, NOF, ClNO₂, FNO₂, PCl₃, PCl₅, PF₃, SF₆.

The reaction gas container may, for example, be adapted such that a reaction gas comprising oxygen may be reliably stored. For example, the reaction gas container may comprise an inner coating such that a gas comprising oxygen may not (substantially) interact with the (inner) material of the reaction gas container. The gas comprising oxygen may comprise at least one oxygen atom. For example, the gas comprising oxygen may comprise at least one of the following: O₂, H₂O, H₂O₂, N₂O, NO, NO₂, HNO₃.

The reaction gas container may, for example, be adapted such that a reaction gas comprising hydrogen may be reliably stored. For example, the reaction gas container may comprise an inner coating such that a gas comprising hydrogen may not (substantially) interact with the (inner) material of the reaction gas container. The gas comprising hydrogen may comprise at least one hydrogen atom. For example, the gas comprising hydrogen may comprise at least one of the following: H₂, NH₃, CH₄.

In an example, the apparatus may comprise two or more reaction gas containers for providing the precursor gas, wherein the apparatus is configured to apply a predetermined combination of two or more reaction gases as the precursor gas. For example, the apparatus may comprise a gas line system such that a predetermined ratio of reaction gases may be provided as the precursor gas (e.g., within the activator). For example, the apparatus may be configured to provide a first reaction gas and a second reaction gas as the precursor gas wherein the first and second reaction gases may have a predetermined ratio of X:Y. The ratio may comprise a ratio of a volume, a mass or a number of molecules (and/or atoms) of the respective reaction gases. In another example, the apparatus may be configured to provide a first reaction gas, a second reaction gas and a third reaction gas with a predetermined ratio of X:Y:Z (e.g., a mass ratio of 5:4:1, 3:2:1 or other suitable ratios). Notably, the apparatus may also provide more than four reaction gases to form a precursor gas.

With such a configuration different types of precursor gases may be supplied as a raw material such that a variety of components may be generated from the precursor gas (e.g., a variety of radicals and/or chemical compounds). The apparatus according to the invention may thus enable to create a variety of possible reactions within the activator.

For example, the apparatus may be configured to generate at least one of the following radicals based on an according precursor gas: a fluorine radical, a chlorine radical, an oxygen radical, a nitrogen radical.

For example, the apparatus may be configured to generate at least one of the following chemical compounds based on an according precursor gas: F₂, O₃, OF, O₂F₂, O₂F, OF₂, O₄F₂, O₃F₂, ClO₂, CIO, Cl₂O. In a further example, the apparatus may be configured to generate Halide oxides and/or radicals of the stated chemical compounds (e.g., halide oxides and/or radicals of at least one of the following compounds: F₂, O₃, OF, O₂F₂, O₂F, OF₂, O₄F₂, O₃F₂, ClO₂, CIO, Cl₂O).

For example, the apparatus may be configured to generate an interhalogen (e.g., ClF, ClF₃, ClF₅ and/or further interhalogens).

In an example, the beam unit may be configured to focus the particle beam locally onto the object during the processing. For example, this may enable that a raster scan of the object may be performed with the particle beam. The raster scan may comprise scanning a working area of the object that is composed of various predetermined pixels. The working area may comprise a part within the subarea which is exposed to the component. For the raster scan the focused particle beam may be guided onto every pixel. However, if a pixel is not supposed to be exposed to the particles the beam unit may turn the particle beam (temporarily) off (which may also be referred to as blanking). If a pixel is supposed to be exposed to the particles the beam unit may turn the particle beam (temporarily) on. In another example, the apparatus may also be configured to perform a vector scan with the particle beam (as known in the field).

In an example, the beam unit may be configured such that a focus area of the particle beam on the object may comprise an area with a diameter of at most 10 μm, at most 1 μm, at most 500 nm, at most 100 nm, at most 10 nm and/or at most 1 nm. In an example, the diameter of the focus area achievable with the beam unit may comprise at least 0.5 nm.

In an example, the beam unit may be configured such that the resolution of the focused particle beam may comprise a resolution smaller than 10 μm, smaller than 1 μm, smaller than 500 nm, smaller than 100 nm, smaller than 10 nm and/or smaller than 1 nm. In an example, the resolution achievable with the beam unit may comprise at least 0.5 nm.

In an example, the beam unit may be configured to provide the particle beam within a specific partial area of the object. For example, the particle beam may be provided on one or more locations within the specific partial area without requiring spatially repositioning or adjusting the object. For example, the specific partial area of the object may comprise a field of view of the beam unit. The particle beam may, for example, be positioned within the field of view on the object based on a control of the beam unit. For example, the particle beam may be deflected and/or focused within the field of view without requiring a spatial adjustment of the object.

The specific partial area (e.g., the field of view) of the beam unit may be defined by a rectangular area (however, also other shapes of the specific partial area may be conceivable). For example, the field of view may comprise a lateral extent (e.g., a lateral extent of a side of the rectangular area of the field of view). The lateral extent of one side of the field of view may, for example, comprise at most 20 μm, at most 10 μm, at most 8 μm, at most 7 μm, at most 5 μm, at most 4 μm, at most 3 μm and/or at most 2 μm.

In an example, the specific partial area (e.g., the field of view) provided by the beam unit may comprise an area defined by the following (exemplary) dimensions: 20 μm×20 μm, 10 μm×10 μm, 8 μm×8 μm, 7 μm×7 μm, 5 μm×5 μm, 4 μm×4 μm, 3 μm×3 μm and/or 2 μm×2 μm. For example, the field of view may substantially be in the shape of a rectangle (e.g., a square) having dimension of 8 μm×8 μm.

In an example, the apparatus may be configured to remove a material of the object based at least in part on the component and the particle beam provided locally on the object. For example, the apparatus may be configured for a particle induced etching of a material of the object with the provided component. To that regard, the apparatus may be configured to continuously provide the component at a reaction area of the object while the beam unit scans various positions (e.g., pixels) within the reaction area to induce an etching reaction in the vicinity of the impinging (e.g., focused) particle beam.

For example, the apparatus may be configured for a (focused) electron beam induced etching (e.g., termed (F)EBIE) of the object via the component. In such an example, the beam unit may be configured to provide an electron beam as a particle beam.

For example, the apparatus may be configured for a (focused) ion beam induced etching and/or milling of the object via the component. In such an example, the beam unit may be configured to provide an ion beam as a particle beam.

For example, the apparatus may be configured for an electron and ion beam induced etching/milling of the object via the component. In such an example, the beam unit may be configured to provide an electron beam and an ion beam.

In some examples, also an apparatus may be conceivable that does not comprise a beam unit. For example, the object may be processed by providing the component locally on the object.

In an example, the apparatus may comprise a control unit for controlling various (herein described) parts and/or units of the apparatus. The control unit may, for example, be configured to control at least one of the following: the activator, the beam unit, the guide, the object holder, one or more gas line systems of the apparatus. The control unit may, for example, comprise a computer and/or a computing unit capable of data processing and/or sending control signals to various parts and/or units of the apparatus.

In an example, the apparatus may be configured to repair the object by removing a material of the object. For example, the apparatus may be configured to repair a mask for lithography.

A second aspect relates to a further apparatus for processing an object. The apparatus may comprise an activator for activating a precursor gas to generate a component from the precursor gas and a beam unit for providing a focused particle beam locally on the object. Notably, all aspects described herein for the apparatus according to the first aspect may also be accordingly applied to the apparatus according to the second aspect.

The apparatus according to the second aspect may, however, not (necessarily) comprise the guide described herein for the first aspect. For example, the component may be introduced globally over the entire object with the apparatus according to the second aspect. For example, the activator may be positioned adjacent to the first chamber comprising the object holder. An aperture, a nozzle and/or an injection system between the activator and the first chamber may be comprised by the apparatus to introduce the component (globally) onto the object.

The apparatus according to the second aspect may, however, be configured to provide a focused particle beam (as described herein) such that a highly localized processing of the object can (nonetheless) be enabled. For some applications it may not be needed to provide the generated component in a local manner. However, for some applications it may be required that the particle induced reaction is confined within a narrow spatial working area which the particle beam needs to scan. The working area may comprise dimensions below 10 μm, below 1 μm, below 500 nm and/or below 100 nm and/or below 60 nm, for example. To reliably process parts (e.g., pixels) of such a narrow working area a focused particle beam may be provided by the beam unit. To that regard the beam unit may comprise an according focusing unit to focus the particle beam to the herein described focus area and/or resolutions. The (narrow) working area may, for example, comprise structures and/or defects of the object (e.g., structures of a mask, a wafer and/or a microchip) that need to be processed.

A third aspect relates to a method for processing an object. The method may comprise activating a precursor gas to generate a component from the precursor gas; providing the component locally on the object; providing a particle beam on the object.

In an example, the component may be provided on a subarea of the object such that substantially only the subarea is exposed to the component, wherein the particle beam is provided within the subarea.

In an example, the method may be performed with an apparatus according to the first aspect (and/or second aspect).

In an example, the method may comprise removing a material of the object based at least in part on the component and the particle beam.

In an example, the activating of the precursor gas may comprise forming a plasma of the precursor gas.

In an example, the activating of the precursor gas may comprise ionizing the precursor gas.

In an example, the method may further comprise providing a predetermined combination of two or more reaction gases as the precursor gas to generate a predetermined component based thereon.

In an example, the method may comprise filtering a specific component out of a plurality of components generated from the precursor gas such that the specific component is provided locally on the object.

In an example, the method may comprise continuously providing the component and the particle beam locally on the object. The component and the particle beam may thus be provided on the object in one processing step. During this continuous processing the particle beam may be (shortly) blanked, however, the component may be nonetheless continuously provided on the object (e.g., continuously ejected onto the subarea). A separate processing with firstly merely subjecting a subarea of the object to the component and subsequently processing the subarea merely with the particle beam (without providing the component) may thus be avoided. Such a separate processing would constitute a prolonged processing time wherein the effects of the component on the object may not persist until the particle beam is guided onto the subarea such that the particle induced reaction may not be initiated at all or with comparably less efficiency (e.g., a smaller etching rate and/or only one etching step possible). The continuous approach according to the invention may enable not only to etch one or several atomic layers of the object. Rather, since the component may be provided continuously with the particle beam a continuous etching is made possible allowing for a variety of etching depths to be realized within one processing step.

In an example, the method may comprise changing at least one particle beam parameter during processing. For example, the method may comprise changing a focus of the particle beam. In another example, the method may comprise changing a beam current and/or an acceleration of the particles of the particle beam.

In an example, the method may be used to repair the object. For example, a defect of the object may be repaired by removing a material of the object.

A fourth aspect relates to a method for processing an object. The method may comprise activating a precursor gas to generate a component from the precursor gas; providing the component on the object and focusing a particle beam on the object. For example, the method may comprise providing the component globally over the entire object. Additionally, or alternatively, the method may also comprise providing the component locally on the object (as described herein).

In some examples, the methods of the third and/or fourth aspects may be implemented as methods for processing an object for lithography, a method for processing a semiconductor-based wafer and/or a method for processing a microchip.

A fifth aspect relates to a computer program. The computer program may comprise instructions for carrying out the method of the third aspect (and/or a method of any other aspect described herein), when the instructions are executed.

In an example, the computer program when executed by a computer and/or an apparatus according to the first aspect (and/or an apparatus of any other aspect described herein) may cause the computer and/or apparatus to execute a method according to any of the herein described aspects.

A further aspect relates to a (non-transitory storage) medium which comprises the herein described computer program.

The apparatuses described herein may be configured to implement a herein described method and/or computer program. For example, an apparatus according to the invention may be configured to receive instructions from the executed computer program which may cause the respective apparatus to perform an according method. For example, the respective apparatus may comprise the storage medium which comprises the computer program wherein the apparatus may execute the computer program (e.g., via its control unit). However, the computer program may also be stored externally (e.g., on a server, in a cloud, etc.) wherein the respective apparatus may comprise a receiver unit to receive the instructions from the externally executed computer program to perform the according method.

It is noted that the method steps (or computer program steps) as described herein may comprise all aspects described herein, even if not expressly described as method steps but rather with reference to an apparatus (or device or system). Moreover, the apparatus (or systems or devices) as outlined herein may comprise means for implementing all aspects as outlined herein, even if these may rather be described in the context of method steps (or computer program steps).

Whether described as method steps, computer program and/or means, the functions described herein may be implemented in hardware, software, firmware, and/or combinations thereof. If implemented in software/firmware, the functions may be stored on or transmitted as one or more instructions or code on a computer-readable medium. Computer-readable media include both computer storage media and communication media including any medium that facilitates transfer of a computer program from one place to another. A storage medium may be any available media that can be accessed by a general purpose or special purpose computer. By way of example, and not limitation, such computer-readable storage media can comprise RAM, ROM, EEPROM, FPGA, CD/DVD or other optical disk storage, magnetic disk storage or other magnetic storage devices, solid state drives, or any other medium that can be used to carry or store desired program code means in the form of instructions or data structures and that can be accessed by a general-purpose or special-purpose computer, or a general-purpose or special-purpose processor. The control unit as described herein may also be implemented in hardware, software, firmware, and/or combinations thereof, for example, by use of one or more general-purpose or special-purpose computers, and/or one or more general-purpose or special-purpose processors.

A fifth aspect relates to an object, wherein the object has been processed with a herein described method (e.g., a method according to the third and/or fourth aspect). The object may comprise an object for lithography (e.g., a mask and/or a mask blank), a (e.g., semiconductor-based) wafer and/or a microchip (as described herein).

A sixth aspect relates to a method for a lithographic processing of a (e.g., semiconductor-based) wafer comprising lithographically transferring a pattern associated with an object for lithography onto the wafer, wherein the object for lithography has been processed with a herein described method (e.g., a method according to the third and/or fourth aspect). The lithographic transferring may comprise a lithographic method which the object for lithography is designed for (e.g., EUV-lithography, DUV-lithography, i-line-lithography, etc.). For example, the method may comprise providing a radiation source that may radiate electromagnetic radiation (e.g., EUV-radiation, DUV-radiation, i-line-radiation, etc.). The method may further comprise providing a resist layer on the wafer (e.g., comprising a photoactive resist). The lithographic transferring may be based at least in part on the radiation of the radiation source and providing the resist layer. For example, the object for lithography may be irradiated via the radiation source such that a pattern of the object may be imaged onto the resist layer.

### BRIEF DESCRIPTION OF DRAWINGS

FIG. 1 shows an exemplary schematic of an apparatus according to the invention.

FIG. 2 shows a first example of a part of an apparatus according to the invention comprising the activator.

FIG. 3 shows a second example of a part of an apparatus according to the invention comprising the activator.

FIG. 4 shows a third example of a part of an apparatus according to the invention comprising the activator.

FIG. 5 shows an example of a part of an apparatus according to the invention comprising the guide, the object and the beam unit.

### DETAILED DESCRIPTION

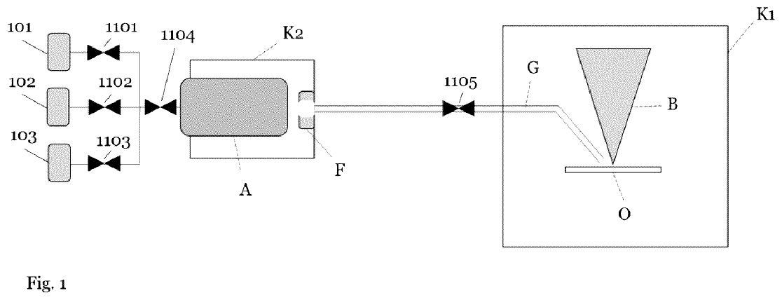

FIG. 1 shows an exemplary schematic of an apparatus 100 according to the invention. As described herein, the apparatus 100 may be used for processing an object O. The object O may comprise a mask or a mask blank for lithography (as described herein). The object O may also comprise a wafer and/or a microchip (as described herein).

First a short overview of the apparatus is given.

The apparatus 100 may comprise a first chamber K1 where the object O may be placed for a particle induced processing. To that regard a particle beam B may be provided on the object O in the first chamber. The apparatus 100 may further comprise a second chamber K2. The second chamber may comprise an activator A for activating a precursor gas to generate a component from the precursor gas. The first chamber K1 and the second chamber K2 may be coupled via a guide G such that a substance may be transported from the second chamber to the first chamber via the guide G. For example, the component generated from the precursor gas may be transported from the second chamber K2 to the first chamber K1 for the particle induced processing of the object O.

Subsequently, a more detailed description is given for the exemplary apparatus 100 in view of an exemplary process sequence according to the invention.

The apparatus may comprise one or more reaction gas containers which may comprise a respective reaction gas. The apparatus of FIG. 1 shows three exemplary reaction gas containers 101, 102, 103. The first reaction gas container 101 may store a first reaction gas. The second reaction gas container 102 may store a second reaction gas. The third reaction gas container 103 may store a third reaction gas. For example, the first reaction gas may comprise a plasma initiating gas (e.g., a gas comprising Argon). For example, the second reaction gas may comprise a gas comprising a halide. For example, the third reaction gas may comprise a gas comprising oxygen. The apparatus may also comprise a fourth reaction gas container (not shown), wherein the fourth reaction gas stored in the fourth reaction gas container may comprise hydrogen. Notably, a reaction gas may also comprise a halide and oxygen, or a halide and hydrogen, or oxygen and hydrogen, or a halide and oxygen and hydrogen. In some examples, only one, two or three of the gas containers may be provided, and it is also conceivable that more than four gas containers are provided.

Each reaction gas container may be coupled to a respective valve. In FIG. 1 the first reaction gas container 101 may be coupled to a first valve 1101. The second reaction gas container may be coupled to a second valve 1102. The third reaction gas container may be coupled to a third valve 1103. The first, second and third valves may be coupled to an activator valve 1104. The activator valve 1104 may be coupled to the activator (e.g., to the inner chamber of the activator A). The valves may be used to control the gas flow of the reaction gases into the activator in a defined manner. The valves that control the flow of the reaction gases to the activator may be considered a gas line system of the apparatus 100 which may be controlled by a control unit of the apparatus 100.

For example, via the valves, it may be controlled which reaction gas may flow into the activator A. The reaction gases which are released into the activator may form the herein described precursor gas. In an example, the first, second and third reaction gases may be released into the activator A. Hence, the precursor gas in this example would be formed out of the first, second and third reaction gases.

Notably, via the valves it may be controlled that two or more reaction gases are released into the activator A such that a predetermined ratio of the reaction gases is present in the activator A. For example, the first, second and third reaction gases may be transported to the activator via the valves such that a predetermined ratio thereof is present in the activator A. For example, the ratio of the first to the second to the third reaction gas may be given in the form of X:Y:Z, wherein any ratio may be implemented via the apparatus. For example, the ratio of the first to the second to the third reaction gas may be 5:4:1 (or any other suitable ratio, which may be based on an experimental analysis of the herein described processing).

In summary, the apparatus 100 may enable via the reaction gas containers and control of the valves that a predetermined gaseous mix is present in the activator A as a precursor gas.

In an example, the apparatus may be configured for processing the object with the component generated from the precursor gas and/or with the precursor gas itself.

For example, the apparatus may be configured such that via guide G and/or a similar but separate guide (not shown), the precursor gas may be provided locally on the object. For example, the precursor gas may be supplied to chamber K1 without passing through the activator A (not shown). In another example, the precursor gas may be supplied to chamber K1 by passing through the activator, wherein the activator is not activated such that the precursor gas is not activated such that the precursor gas is provided locally on the object (not shown).

All aspects described herein for processing the object with the component may, for example, also apply for processing the object with the precursor gas itself.

For example, the herein described properties and/or features of the guide (for providing the component locally on the object) may also apply to the guide for providing the precursor gas locally on the object.

For example, the guide for providing the component locally on the object may be used as a guide for providing the precursor gas locally on the object.

However, the guide for providing the precursor gas locally on the object may, for example, also be a separate guide than the guide for providing the component locally on the object. Notably, in this example, the herein described features of the guide for providing the component locally on the object may (at least in part) be features of the guide for providing the precursor gas locally on the object.

The activator A may comprise a plasma unit. The plasma unit may be configured to ignite a plasma of the precursor gas. To that end, the plasma unit may be any type of configuration that can ignite a plasma of a gaseous mix. For example, the plasma unit may comprise two electrodes in its inner chamber. The precursor gas received by the activator A may be present between the two electrodes. An electrical field (with a certain power and frequency) may be applied between the two electrodes by the apparatus to excite the precursor gas such that a plasma of the precursor gas is ignited. The plasma unit may comprise a magnetic field 30) generator to suspend the plasma to a magnetic field for further adapting the plasma. The plasma unit may be configured such that a plasma filamentation is inhibited or not present.

The plasma initiating gas (e.g., Argon) present in the precursor gas may assist in inducing the plasma of the precursor gas. For the excitation, the frequency of the electrical field may comprise a frequency of 13.56 MHz. The frequency may also be in the range of 40 kHz to 100 kHz. The frequency may also comprise a frequency of 2.45 GHz. The power of the excitation of the plasma may be in the range of 100 W to 1600 W. The pressure for generating the plasma may, for example, be in the range of atmospheric pressure and up to 1*10⁻⁴ mbar.

The ignited plasma of the precursor gas may generate components which were not present in the (initial) precursor gas itself. For example, the components of the plasma may comprise (highly) reactive species and/or new chemical compounds which were not present in the (not activated) precursor gas (or the reaction gas containers). For example, the plasma may generate free radicals which may be highly reactive with respect to a material of the object O. For example, the generated radicals may be neutral in charge. However, via the plasma also electrically charged radicals (e.g., positively or negatively charged radicals) may be generated. The generated radicals may be locally provided on the object by the apparatus for a particle induced reaction in combination with the radicals (as described herein).

As stated herein, the plasma may also generate specific new chemical compounds as components which may be based on the provided reaction gases that form the precursor gas.

However, not every component of the plasma may be useful for the particle induced reaction on the object O. To that regard, the apparatus may be configured to filter a certain component out of the generated components of the plasma.

For example, the plasma unit may be comprised by the second chamber K2. The second chamber K2 may comprise a vacuum chamber wherein the plasma unit is placed within the vacuum chamber (or wherein at least a part of the plasma unit resides within the vacuum chamber). The plasma unit may comprise an aperture and/or nozzle to eject one or more components of the plasma from the plasma unit into the vacuum chamber of the second chamber K2. The plasma unit may also comprise an ejection system which may comprise one or more apertures and/or nozzles for ejecting one or more components into the vacuum chamber.

The components ejected from the plasma unit may thus travel freely within the vacuum chamber. The ejected components may, for example, form a beam with a wide angular distribution (e.g., dependent on the aperture size or nozzle characteristics). An input opening of the guide G may be placed within the travel path of the generated component such that the components may reach the input opening.

The second chamber K2 may further comprise a filter F placed therein to filter out certain components. The filter F may be placed between the plasma unit and the input opening of the guide G. The filter F may comprise an ion filter and/or a neutralization plate. The filter F may allow that only a particularly charged component may be coupled into the guide G. For example, the ion filter may be configured to apply an electrical and/or magnetic field to deflect one or more particularly charged components such that only a desired component may be coupled into the guide. For example, the ion filter may deflect positively and negatively charged components away from the input opening of the guide G such that (substantially) only neutral components may be coupled into the guide G.

The filter F may also comprise a neutralization plate which may be electrically grounded. As described herein, charged components may thus be absorbed by the neutralization plate wherein neutral components may diffuse through the neutralization plate into the guide G.

The guide G may comprise a guide valve 1105. The guide valve 1105 may be used to control the flow of the generated component within the guide G. The guide valve 1105 may thus be used to control the flow of the component into the first chamber K1 and thus a control of the flow of the generated component onto the object O.

In FIG. 1 it is shown that the guide G extends within the first chamber K1. The guide G extends such that an output opening of the guide is positioned in a vicinity of the object O. Hence, the generated component may be provided locally on the object.

Furthermore, in FIG. 1 the particle beam B within the first chamber K1 is schematically shown. Notably, a focused particle beam is schematically depicted. The particle beam B may be locally provided within an area of the object where the generated component is provided (as described herein). The particle beam B may comprise an electron beam. The apparatus 100 may, for example, be configured to induce a (focused) electron beam induced etching with the provided generated component. The particle beam B may also comprise an ion beam. The apparatus 100 may, for example, be configured to induce a (focused) ion beam induced etching with the provided generated component. The apparatus may also be configured to provide two or more particle beams (e.g., a dual-beam setup) wherein, for example, an electron beam and an ion beam may be provided in the first chamber K1.

As stated herein, the particle induced reaction with the generated component may be more effective compared to a particle induced reaction with only the precursor gas itself.

Namely, the radicals or specifically generated chemical compounds from the precursor gas may be more reactive with respect to the surface of the object O. The generated components may, for example, have a higher likelihood of chemisorption on the object than the precursor gas itself. The dwell time of the generated components on the object may thus be comparably longer than the dwell time of the precursor gas on the object. The concentration of the generated component on the object may thus be locally longer and/or more reliably provided which may enable a more effective particle induced reaction (e.g., a faster etching and/or an improved etching of a highly resistive material).

Prior approaches may rely on a local particle induced etching using a simple etching gas provided on a substrate wherein the etching gas comprises comparably unreactive species. For example, the etching gas of common approaches may not comprise radicals (or may only comprise natural radicals such as NO or NO₂). In such approaches the first interaction with the substrate mainly comprises physisorption. The etching gas components may thus accumulate on the substrate by a rather weak binding. Hence, the physiosorbed molecules of the etching gas may (easily) spontaneously desorb from the substrate's surface which may make the particle induced reaction less efficient (since less reaction material is available). It may be possible that (at least in part) spontaneous chemisorption occurs. Chemisorption may constitute a stronger binding of the etching gas components to the substrate. However, the degree of spontaneous chemisorption in common approaches may be comparably low (e.g., since physisorption may regardless dominate due to the unreactive etching gas). Notably, after the etching gas is provided on the substrate the actual activation of the etching gas via the particle beam may occur. However, the particle beam may also actively cause that physisorbed molecules desorb from the substrates surface. Hence, the etching gas needed for the particle induced reaction may be desorbed (at least in part) by the particle beam itself. Common approaches may thus be limited in the efficiency of the reaction due to the easily desorbed molecules which are (mainly) bound to the substrate by physisorption.

However, the invention may enable providing highly reactive components generated from the precursor gas (e.g., radicals and/or highly reactive chemical compounds). Hence, the likelihood of chemisorption of the generated components with the material of the object O may be increased (whereas the likelihood of physisorption of the generated components with the material of the object O may be decreased). For example, components may be generated such that mainly chemisorption dominates the interaction between the component and the surface of the object O. Therefore, a desorption of the component from the surface of the object O may be minimized in view of the particle induced processing of the object. The particle induced reaction with the component may thus be more efficient (e.g., the etching may be faster).

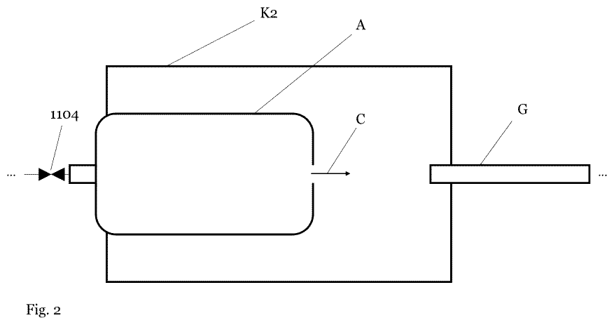

FIG. 2 shows a first example of a part of an apparatus according to the invention comprising the activator. In particular, FIG. 2 shows an exemplary configuration of the second chamber K2. Compared to FIG. 1, the apparatus of FIG. 2 does not comprise a filter. The activator A may comprise a plasma unit which may eject components C of the plasma into the vacuum chamber of the second chamber K2. The input opening of the guide G may be positioned in the travel path of the components C such that the components C may be coupled into the guide G. For example, with a configuration of FIG. 2 components C with various charges may be coupled into the guide. In such an example, the guide G may thus charge up since components C with a net charge other than zero may be absorbed by the guide G. In such a configuration the apparatus may comprise a highly inert guide (e.g., a highly inert inner wall) since a variety of reactive components may interact with the guide. For example, in such a configuration, the inner wall of the guide may comprise a resistive coating (e.g., a Teflon coating). The resistive coating may ensure a prolonged presence of the component in the guide. For example, the coating may be implemented to minimize a reaction with the components such that the components may not easily be absorbed or accumulate on the inner wall.

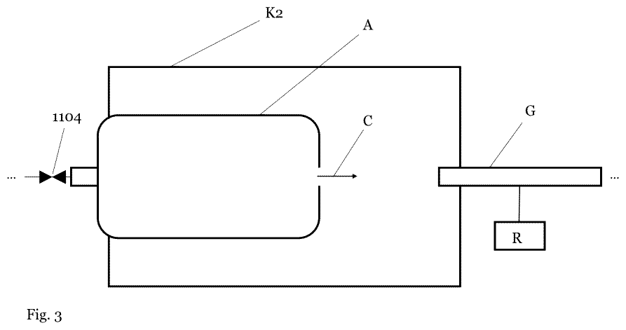

FIG. 3 shows a second example of a part of an apparatus according to the invention comprising the activator. In particular, FIG. 3 shows an exemplary configuration of the second chamber K2, as well. Compared to FIG. 2, the guide G of FIG. 3 is set on a predetermined potential R. For example, the predetermined potential may comprise an electrical ground potential. For example, the predetermined potential may comprise a potential of zero Volts. In such an example, the guide G may function as a filter. Namely, components C of various charges may be coupled into the guide G (as explained for FIG. 2). However, since the guide G may be electrically grounded to the predetermined potential R, components C with positive or negative net charges may be conducted towards the guide and thus absorbed by the guide. Therefore, mainly neutral components C may be guided to the first chamber K1 onto the object O. Furthermore, the configuration of FIG. 3 may enable that the guide G is grounded with respect to the first chamber K1. Hence, it may be minimized that the guide G can induce a charging effect within the first chamber. For example, a charged guide G may interact with the particle beam B and/or the object O in an undesired manner. The configuration according to FIG. 3 may thus minimize potentially interfering effects of a charged guide G within the first chamber K1. For example, a charged guide G may deflect a particle beam B of charged particles. Such a deflection may be minimized (or eliminated) by electrically grounding the guide G (as described herein).

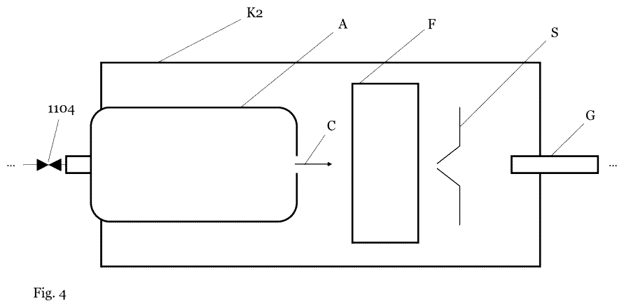

FIG. 4 shows a third example of a part of an apparatus according to the invention comprising the activator. In particular, FIG. 4 shows an exemplary configuration of the second chamber K2, as well. Compared to FIG. 2, a filter F and a beam shaper S are positioned between the activator A (e.g., a plasma unit) and the input opening of the guide G. The filter F may comprise an ion filter as described herein. The components C traveling from the plasma unit may, for example, be deflected by the filter depending on their charge. For example, only neutral components C may pass the ion filter unaffected. Along the further travel path a skimmer may be positioned as a beam shaper S. The skimmer may comprise a funnel shape. For example, the skimmer may comprise a molecular beam skimmer. The skimmer may be positioned within the apparatus such that angular distribution of the (e.g., neutral) component C that has passed through the filter F is reduced. For example, the skimmer may be adapted to collimate the beam of the component C. This may enable a more effective coupling of the component C into the 20) guide. For example, the skimmer may enable that the beam diameter of the component C may substantially reside within the input opening of the guide.

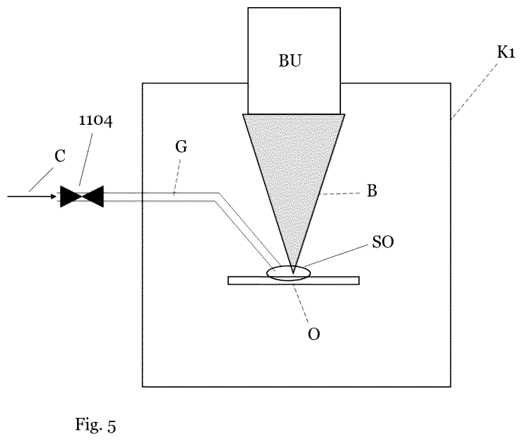

FIG. 5 shows an example of a part of an apparatus according to the invention comprising the guide G, the object O and the beam unit BU. Notably, the first chamber K1 is shown comprising the object O. The beam unit BU may, for example, extend at least in part into the first chamber K1, as well. The beam unit BU may, for example, comprise one or more beam shaping and/or beam focusing elements. The beam unit BU may, for example, comprise a particle source for the particle beam B. For example, the beam unit BU may comprise beam shaping and/or focusing elements known from scanning electron microscopy when the particle beam B comprises an electron beam. For example, the beam unit BU may comprise beam shaping and/or 30 focusing elements known from focused ion beam apparatuses when the particle beam B comprises an ion beam.

The beam unit BU may be configured to adapt various beam parameters for the particle induced processing of the object. The beam unit BU may also be configured for imaging purposes. For example, the beam unit BU may be adapted to generate an image of the object O via the particle beam.

Furthermore in FIG. 5, the local extent of the component C on the object O is again schematically depicted. An output opening of the guide G may be positioned in a vicinity to the object O wherein the output opening may release the component C onto the object O. Due to the guide's G position the component may thus only be provided within a subarea SO of the object. Other areas of the object O may not be exposed to the component C. The beam unit BU may be configured to guide the particle beam B into (a part of) the subarea SO to induce a particle induced reaction in the subarea. If the particle beam B were guided onto a part outside of the subarea SO, (substantially) no particle induced reaction would occur, since no (significant) amount of the component C may be present outside of the subarea SO.

For example, the apparatus may be configured such that the global pressure of the first chamber K1 may comprise a pressure in the range of 1*10⁻⁷ mbar to 1*10⁻⁴ mbar. This pressure may be held during the processing of the object with the component. However, the local pressure within the subarea (e.g., the local pressure of the component C) may comprise in comparison a pressure of a higher magnitude. For example, the local pressure of the component C may comprise a pressure of 1*10⁻³ mbar to 1*10⁻² mbar.

For example, the beam unit BU may be configured to set a specific extraction voltage for the particle beam (e.g., for the electron and/or ion beam) for the particle induced process. The extraction voltage may, for example, comprise an extraction voltage in the range of 0.1 kV to 3 kV, preferably 0.15 kV to 1 k, more preferably 0.2 kV to 0.8 kV, most preferably 0.3 kV to 0.6 kV.

For example, the beam unit BU may be configured to set a specific beam current for the particle beam (e.g., for the electron and/or ion beam) for the particle induced reaction. The beam current may, for example, comprise a beam current in the range of 1 to 500 pA, preferably 2 to 300 pA, more preferably 5 to 100 pA, most preferably 10 to 60 pA.

Subsequently, processing examples, which may be implemented via an apparatus according to the invention are described.

For example, the object O may comprise a mask for DUV-lithography (i.e., a DUV-mask). The DUV-mask may comprise an absorption layer for absorbing DUV-light. For example, pattern elements may be formed out of the absorbing layer on the DUV-mask. The absorbing layer (and/or according pattern elements) may be positioned on a cover layer of the DUV-mask. The absorbing layer may comprise silicon nitride (e.g., SiN). The cover layer may comprise a silicon oxide (e.g., SiO₂). Notably, the DUV-mask may comprise a mask defect. For example, parts of the DUV-mask may comprise the absorbing layer which, however, by design should not be the case. Such a material may be considered excessive absorber material (and may also be termed dark defect).

In an example, a method according to the invention may comprise removing excessive absorber material of the DUV-mask. Hence, via the apparatus excessive material comprising silicon nitride may be removed. To that regard, a high etch selectivity with respect to the cover layer comprising a silicon oxide may be desired. Namely, the particle induced process should remove excessive absorber material while not (significantly) attacking/removing the adjacent cover layer. For example, for etching silicon nitride on a layer of silicon dioxide a specific precursor gas may be provided by the apparatus which may be activated as described herein. For example, an according precursor gas may comprise a gaseous mix of Argon, CF₄ and O₂ which may be provided to the activator via respective reaction gases. In an example, the ratio of Argon to CF₄ to O₂ in the precursor gas may comprise a ratio of 5:4:1. This gaseous mix corresponding to the precursor gas may be activated within the plasma unit of the apparatus. For example, the plasma unit may form a plasma of the precursor gas based on an excitation frequency of 13.56 MHz and a power between 400 W and 100 W. The plasma of the precursor gas may then comprise reactive species (e.g., neutral or charged radicals). In an example, the neutral species generated in the plasma (e.g., neutral radicals) may be filtered and transported to the object O via the guide G (as described herein). The neutral species may thus reside in a subarea of the object O. Due to the reactive nature of the generated neutral component a chemisorption of the neutral component on the surface of the object may occur. Subsequently, the particle beam may be provided in the form of an electron beam within the subarea to induce an electron induced etching of the silicon nitride with the neutral species. The neutral species generated from the gaseous mix of the precursor gas may enable a selective etching of the silicon nitride with respect to the silicon oxide.

Notably, the selectivity may be tuned by varying the ratio of the gas components of the precursor gas (e.g., by varying the ratio of Argon to CF₄ to O₂ present in the precursor gas). The selectivity may also be tuned by adapting at least one plasma influencing parameter of the plasma unit. The selectivity may also be tuned by adapting at least one beam parameter of the particle beam B provided on the object O.

In another example, the object O may comprise a mask for EUV-lithography (i.e., a EUV-mask). The EUV-mask may comprise a first absorption layer comprising ruthenium (Ru). The EUV-mask may further comprise a second absorption layer comprising tantalum (Ta). The first absorption layer may be positioned on the second absorption layer. A pattern element may be formed out of the first and second absorption layer. The EUV-mask may further comprise a capping layer. The capping layer may comprise ruthenium (Ru) and/or rhodium (Rh). The second absorption layer may be positioned on the capping layer. The EUV-mask may thus, for example, have a layer stack in the following sequence: the first absorption layer (with Ru), the second absorption layer (with Ta) and the capping layer (with Ru and/or Rh). It may be desired to remove a part of the first absorption layer comprising ruthenium while not (significantly) attacking/removing the second absorption layer below. It may thus be desired to etch a part of the first absorption layer with a high selectivity with respect to the second absorption layer. For example, it may be desired to remove excessive material of the first absorption layer when it may form a dark defect on the EUV-mask.

20) In an example, a method according to the invention may comprise removing a material comprising ruthenium with a sufficient selectivity with respect to a material comprising tantalum. For example, an according precursor gas may comprise a gaseous mix of Ar, CCl₄ and O₂. In an example, the ratio of Argon to CCl₄ to O₂ in the precursor gas may comprise a ratio of 5:4:1. In another example, an according precursor gas may comprise a gaseous mix of Ar, Cl₂ and O₂. In an example, the ratio of Argon to Cl₂ to O₂ in the precursor gas may comprise a ratio of 5:4:1. This gaseous mix corresponding to the precursor gas may be activated within the plasma unit of the apparatus. For example, the plasma unit may form a plasma of the precursor gas based on an excitation frequency of 13.56 MHz and a power between 400 W and 100 W. As described herein, the neutral species generated in the plasma may be guided onto a subarea of the object. The particle beam may be provided in the form of an electron beam within the subarea to induce an electron induced etching of the ruthenium with the neutral species. The neutral species generated from the gaseous mix of the precursor gas may enable a selective etching of the ruthenium with respect to tantalum comprising material.

Notably, the selectivity may be tuned by varying the ratio of the gas components of the precursor gas (e.g., by varying the ratio of Argon to CCl₄ to O₂ or Argon to Cl₂ to O₂ present in the precursor gas'). The selectivity may also be tuned by adapting at least one plasma influencing parameter of the plasma unit. The selectivity may also be tuned by adapting at least one beam parameter of the particle beam B provided on the object O.

While the disclosure has been described in connection with certain examples, it is to be understood that the disclosure is not to be limited to the disclosed examples but, on the contrary, is intended to cover various modifications and equivalent arrangements included within the scope of the appended claims, which scope is to be accorded the broadest interpretation so as to encompass all such modifications and equivalent structures as is permitted under the law.

What is claimed is:

1. An apparatus for processing an object, the apparatus comprising:
an activator for activating a precursor gas to generate a component from the precursor gas;
a guide for providing the component locally on the object; and
a beam unit for providing a particle beam on the object.

2. The apparatus of claim 1, wherein the guide is configured such that the component can be provided on a subarea of the object such that substantially only the subarea is exposed to the component.

3. The apparatus of claim 1, wherein the apparatus has a first chamber comprising a holder for the object, wherein the guide extends at least in part within the first chamber.

4. The apparatus of claim 1, wherein in a processing position of the object an opening of the guide which releases the component onto the object is spaced from the object by at most 10 cm, by at most 1 cm, by at most 100 μm, or by at most 10 μm.

5. The apparatus of claim 1, wherein an inner wall of the guide comprises a coating which is substantially resistant to the component.

6. The apparatus of claim 5, wherein the coating comprises at least one of the following materials or a combination thereof: Teflon, steel, a plastic, or a dielectric material.

7. The apparatus of claim 1, wherein the activator is separated from the object such that the object is not subjected to a reaction of the activating of the precursor gas.

8. The apparatus of claim 2, wherein the apparatus has a second chamber comprising the activator, wherein the second and first chambers are coupled at least in part via the guide such that the component may be transported from the second chamber to the first chamber.

9. The apparatus of claim 1, wherein the activator comprises a plasma unit to form a plasma for activating the precursor gas.

10. The apparatus of claim 9, wherein the component comprises a component of the plasma.

11. The apparatus of claim 1, wherein the activator comprises a radiation unit to irradiate the precursor gas with electromagnetic radiation to ionize the precursor gas for activating the precursor gas.

12. The apparatus of claim 11, wherein the component comprises a component of the ionized precursor gas.

13. The apparatus of claim 1, wherein the component comprises a radical and/or a chemical compound not substantially present in the precursor gas.

14. The apparatus of claim 1, wherein the apparatus comprises a filter for filtering a specific component out of a plurality of components generated from the precursor gas such that the specific component is provided locally on the object.

15. The apparatus of claim 14, wherein the filter comprises an ion filter and/or a neutralization plate.

16. The apparatus of claim 14, wherein the apparatus is configured to set the guide on a predetermined electric potential to filter the specific component.

17. The apparatus of claim 1, wherein the activator is configured to eject the component in a beam to the guide.

18. The apparatus of claim 17, wherein the apparatus comprises a beam shaper to shape the beam of the component ejected from the activator.

19. The apparatus of claim 1, wherein the apparatus comprises at least one reaction gas container for providing the precursor gas, wherein the at least one reaction gas container is configured to store at least one of the following: a reaction gas comprising a halide, a reaction gas comprising oxygen, a reaction gas comprising hydrogen.

20. The apparatus of claim 1, wherein the apparatus comprises two or more reaction gas containers for providing the precursor gas, wherein the apparatus is configured to apply a predetermined combination of two or more reaction gases as the precursor gas.

21. The apparatus of claim 1, wherein the beam unit is configured to focus the particle beam locally onto the object during the processing.

22. The apparatus of claim 1, wherein the apparatus is configured to remove a material of the object based at least in part on the component and the particle beam provided locally on the object.

23. A method for processing an object, the method comprising:
activating a precursor gas to generate a component from the precursor gas;
providing the component locally on the object; and
providing a particle beam locally on the object.

24. The method of claim 23, wherein the component is provided on a subarea of the object such that substantially only the subarea is exposed to the component, wherein the particle beam is provided within the subarea.

25. The method of claim 23, wherein the method is performed with an apparatus for processing the object, the apparatus comprising:
an activator for activating the precursor gas to generate the component from the precursor gas;
a guide for providing the component locally on the object; and
a beam unit for providing the particle beam on the object.

26. A computer program comprising instructions for carrying out the method of claim 23, when the instructions are executed.

27. A computer-readable medium storing a computer program comprising instructions that when executed by one or more computers cause the one or more computers to carry out the method of claim 23.
